(19) United States
(12) Patent Application Publication
(10) Pub. No.: US 2019/0062920 A1
(43) Pub. Date: Feb. 28, 2019

(54) Method for Producing Flexible Substrate, Flexible Substrate and Flexible Display Panel

(71) Applicant: BOE TECHNOLOGY GROUP CO., LTD., Beijing (CN)

(72) Inventor: Changhan HSIEH, Beijing (CN)

(21) Appl. No.: 16/021,833

(22) Filed: Jun. 28, 2018

(30) Foreign Application Priority Data
Aug. 22, 2017 (CN) 201710726119.0

(51) Int. Cl. C23C 16/50; C23C 16/34; C23C 16/40; B32B 17/10; C03C 17/245; C03C 17/34

(52) U.S. Cl. CPC C23C 16/50; C23C 16/345; C03C 17/3405; B32B 17/10018; C03C 17/2453; C23C 16/401

(57) ABSTRACT

The present disclosure relates to a method for producing flexible substrate, a flexible substrate, and a flexible display panel. The method comprises: providing a substrate, and forming a first flexible material layer on a surface of the substrate; forming an inorganic barrier layer on a surface of the first flexible material layer, wherein the inorganic barrier layer includes at least one of a silicon oxide material layer and a silicon nitride material layer; after forming the inorganic barrier layer, performing a plasma bombardment treatment on the surface of the inorganic barrier layer to improve the wettability of the surface of the inorganic barrier layer; and forming a second flexible material layer on the surface of the inorganic barrier layer, and then peeling off the substrate. The second flexible material layer can be well attached to the inorganic barrier layer. The present disclosure can simplify the producing process and decrease cost.

### FIELD OF THE INVENTION

The present disclosure relates to the field of display panel technology, and in particular to a method for producing flexible substrate, a flexible substrate prepared by the method, and a flexible display panel including the flexible substrate.

### BACKGROUND OF THE INVENTION

With the development of technology and the progress of society, various display devices have been used in a large number of applications in lifestyle. On the basis of the extensive use of these display devices, a paper-like ultra-thin flexible display device, which can be bent and has good portability, is considered as a next-generation display device.

The current market demand for ultra-thin flexible display products is increasing. In order to meet the product demand, more display devices will adopt flexible materials such as plastics, metals, etc. to make display substrates. For example, Polyimide (PI) materials are widely used because of their excellent material properties.

It should be noted that, the information disclosed in the foregoing background section is only for enhancement of understanding about the background of the disclosure and therefore may include information that does not constitute prior art known to those skilled in the art.

### SUMMARY OF THE INVENTION

An object of the present disclosure is to provide a method for producing flexible substrate, a flexible substrate prepared by the method, and a flexible display panel including the flexible substrate, so as to overcome one or more problems in some degree caused by the limitations and defects of the related art.

Other features and advantages of the present disclosure will be apparent from the following detailed description, or may be learned in part through the practice of the present disclosure.

According to a first aspect of embodiments of the present disclosure, there is provided a method for producing flexible substrate, the method comprising: providing a substrate, and forming a first flexible material layer on a surface of the substrate;

farming an inorganic barrier layer on a surface of the first flexible material layer, wherein the inorganic barrier layer includes at least one of a silicon oxide material layer and a silicon nitride material layer;

after forming the inorganic barrier layer, performing a plasma bombardment treatment on a surface of the inorganic barrier layer to improve the wettability of the surface of the inorganic barrier layer; and

forming a second flexible material layer on the surface of the inorganic barrier layer, and then peeling off the substrate.

In an exemplary embodiment of the present disclosure, the step of forming the inorganic barrier layer on a surface of the first flexible material layer includes:

placing the substrate on which the first flexible material layer has been formed in a chamber; and

supplying silane gas to the chamber while providing plasma into the chamber, and then forming the inorganic barrier layer on the surface of the first flexible material layer.

In an exemplary embodiment of the present disclosure, the step of after forming the inorganic barrier layer, performing a plasma bombardment treatment on a surface of the inorganic barrier layer includes:

after forming the inorganic barrier layer, stopping the supply of the silane gas and the plasma, and then continuously introducing nitrous oxide into the chamber for a predetermined time; and

after the nitrous oxide introduced into the chamber reaches a predetermined reaction condition, introducing plasma into the chamber and performing a plasma bombardment treatment on the surface of the formed inorganic barrier layer.

It should be noted that, not only the nitrous oxide introduced in the chamber, but also other parameters such as temperature and pressure in the chamber achieve the predetermined reaction conditions.

In an exemplary embodiment of the present disclosure, the predetermined time is 20 to 300 seconds. By setting the predetermined time, the silane gas in the chamber can be discharged.

In an exemplary embodiment of the present disclosure, the predetermined reaction condition includes that the concentration percentage of the nitrous oxide achieves 95% or more. It should be noted that, the concentration percentage of the nitrous oxide herein refers to the percentage of the nitrous oxide concentration to the total concentration of all gases in the chamber.

In one exemplary embodiment of the present disclosure, the plasma bombardment treatment on the surface of the inorganic barrier layer is performed for 1 to 10 seconds, and the power of the plasma bombardment treatment is 1 to 5 kW.

In an exemplary embodiment of the present disclosure, the step of forming the inorganic barrier layer on a surface of the first flexible material layer includes:

forming the inorganic barrier layer on a surface of the first flexible material layer by a chemical vapor deposition process.

In an exemplary embodiment of the present disclosure, each of the first flexible material layer and the second flexible material layer is a polyimide material layer.

According to a second aspect of the present disclosure, there is provided a flexible substrate including:

a first flexible material layer;

an inorganic barrier layer located on the first flexible material layer, wherein the inorganic barrier layer includes at least one of a silicon oxide material layer and a silicon nitride material layer, the inorganic barrier layer has a surface on which a plasma bombardment treatment has performed, and hydroxyl groups are present on the surface on which the plasma bombardment treatment has performed;

a second flexible material layer located on the inorganic barrier layer.

According to a third aspect of embodiments of the present disclosure, there is provided a flexible display panel including the flexible substrate according to anyone of the above embodiments.

The technical solutions encompassed by embodiments of the present disclosure may achieve the following advantageous effects:

in one embodiment of the present disclosure, after forming the inorganic barrier layer on the surface of the first flexible material layer, a plasma bombardment treatment is performed directly on the surface of the inorganic barrier layer so as to improve the wettability of the surface of the inorganic barrier layer. Accordingly, on the one hand, after forming the inorganic barrier layer (for example, silicon oxide or silicon nitride), a plasma bombardment treatment is performed directly on the surface of the inorganic barrier layer, and the surface of the inorganic barrier layer is modified so that hydroxyl groups are present thereon; as a result, the wettability of the surface of the inorganic barrier layer is improved to ensure that the second flexible material layer (for example, PI layer) can be well attached to the inorganic barrier layer. On the other hand, compared with the prior art, an additional inorganic interface layer is unnecessarily formed to improve the above-mentioned problems such as poor interface adhesion, therefore, the present embodiments optimize the producing technology of a multilayer flexible substrate (for example, a PI flexible substrate), which enables the entire flexible substrate processing to be completed simply and smoothly, while saving the costs, substantially avoiding the problem of poor stress match and impurities caused by the inorganic interface layer, and increasing product yield and quality.

It should be understood that the above general description and the following detailed description are merely exemplary and explanatory but do not limit the present disclosure.

### BRIEF DESCRIPTION OF THE DRAWINGS

The drawings herein are incorporated in and constitute a part of this specification. Moreover, the drawings illustrate embodiments according to the present disclosure, and together with the description serve to explain the principles of the present disclosure. Obviously, the drawings in the following description are merely some embodiments of the present disclosure, and those skilled in the art can also obtain other drawings based on these drawings without any creative work.

FIG. 1 is a flow chart schematically showing a method for producing a flexible substrate according to an exemplary embodiment of the present disclosure;

FIG. 2 is a flow chart schematically showing another method for producing a flexible substrate according to an exemplary embodiment of the present disclosure;

FIG. 3 is a flow chart schematically showing another method for producing a flexible substrate according to an exemplary embodiment of the present disclosure; and

FIG. 4 is a schematic diagram schematically showing the structure of a flexible substrate according an exemplary embodiment of the present disclosure.

### DESCRIPTION OF THE PREFERRED EMBODIMENT

Exemplary embodiments will now be further described with reference to the drawings. However, exemplary embodiments can be implemented in various forms and should not be construed as limited to the examples set forth herein; rather, these embodiments are provided so that the present disclosure will be more comprehensive and integrated, and will fully convey the concept of the exemplary embodiments to those skilled in the art. The features, structures, or characteristics described may be combined in one or more embodiments in any suitable manner.

Moreover, the drawings are merely schematic illustrations of the present disclosure and are not necessarily drawn to scale. The same or similar parts are marked with the same reference numerals in the drawings, and the repeated descriptions will be omitted.

In an exemplary embodiment of the present disclosure, a method for producing a flexible substrate is provided, which may be used to prepare a flexible substrate such as a polyimide flexible substrate. As shown in FIG. 1, the method may include the following steps:

Step S101; providing a substrate, and forming a first flexible material layer on a surface of the substrate;

Step S102: forming an inorganic barrier layer on the surface of the first flexible material layer, wherein the inorganic barrier layer includes at least one of a silicon oxide material layer and a silicon nitride material layer;

Step S103: after forming the inorganic barrier layer, performing a plasma bombardment treatment on the surface of the inorganic barrier layer so that hydroxyl groups are present thereon, thereby improving the wettability of the surface of the inorganic barrier layer; and

Step S104: forming a second flexible material layer on the surface of the inorganic barrier layer, and then peeling off the substrate.

According to the above method for producing a flexible substrate, on the one hand, after forming the inorganic barrier layer (for example, silicon oxide or silicon nitride), a plasma treatment is performed directly on the surface of the inorganic barrier layer, and the surface of the inorganic barrier layer is modified so that hydroxyl groups are present thereon; as a result, the wettability of the surface of the inorganic barrier layer is improved to ensure that the second flexible material layer (for example, PI film layer) can be well attached to the inorganic barrier layer. On the other hand, compared with the prior art, an additional inorganic interface layer is unnecessarily formed to improve the above-mentioned problems such as poor interface adhesion. Therefore, the present embodiment optimizes the producing technology of a multilayer flexible substrate (for example, a PI flexible substrate), which enables the entire flexible substrate processing to be completed simply and smoothly, while saving the costs, substantially avoiding the problem of poor stress match and impurities caused by an inorganic interface layer, and increasing product yield and quality.

In the related art, it is necessary for a flexible display substrate formed of PI to form an inorganic barrier layer so as to improve the properties such as moisture barrier, oxygen barrier, scratch resistance, and the like of the first PI layer. However, the inorganic barrier layer may result in the problems such as the poor interface adhesion between the inorganic barrier layer and the second PI layer. In the related art, an inorganic interface layer is further formed to improve the problem of poor interface adhesion described above. However, the inorganic interface layer may further result in the problems such as poor stress match and impurities. Therefore, it is necessary to provide a new technical solution to improve one or more problems in the related art.

Under the inventive concept of the present disclosure, a complete flexible substrate includes a structure with four layers: a first PI layer, a first inorganic layer, a second PI layer, and a second inorganic layer. The surface of the second layer does not need surface modification, and mainly functions as moisture barrier, oxygen barrier, and anti-scratching. The effects of this layered structure are as follows: 1) increasing the path of the moisture and oxygen achieving the contact surface between the substrate and component; 2) the two PI layers are set to effectively reduce the occurrence rate of affecting the surface roughness degree due to particles during the producing process.

Hereinafter, each step of the above-described method for producing a flexible substrate according to an exemplary embodiment of the present disclosure will be described in detail with reference to FIGS. 1 to 4.

In step S101, a substrate is provided, and a first flexible material layer is formed on a surface of the substrate.

In the present exemplary embodiment, the first flexible material layer 401 may be a polyimide material layer, i.e., a PI material layer. As shown in FIG. 4, a substrate 500 may be provided as a carrier substrate, and a first polyimide material layer, i.e., a first flexible material layer 401 is prepared on a surface of the substrate 500 in advance. The specific process of this step may refer to the known technologies, for example, coating methods may be adopted.

In step S102, an inorganic barrier layer is formed on the surface of the first flexible material layer, wherein the inorganic barrier layer includes at least one of a silicon oxide material layer and a silicon nitride material layer.

Exemplarily, after the first polyimide material layer (i.e., the first flexible material layer 401) is formed, the inorganic barrier layer 402 (i.e., silicon oxide material layer or silicon nitride material layer) may be formed on the surface of the first polyimide material layer.

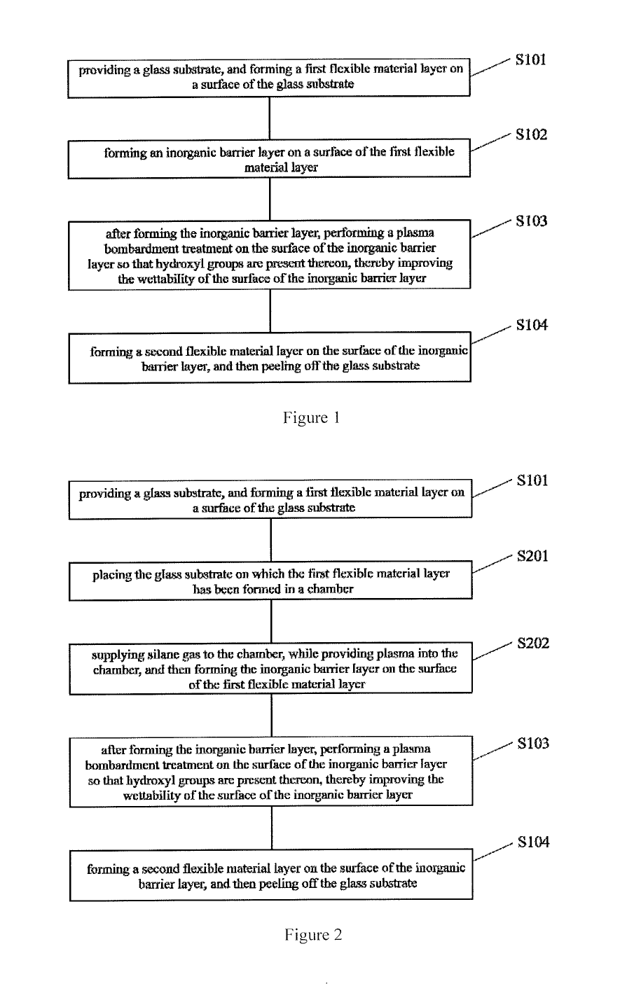

As shown in FIG. 2, in an exemplary embodiment of the present disclosure, Step S102, i.e., forming an inorganic barrier layer 402 on the surface of the first flexible material layer 401, may specifically include the following steps:

Step S201: placing the substrate on which the first flexible material layer has been formed in a chamber. For example, the substrate 500 on which the first polyimide material layer (i.e., the first flexible material layer 401) has been formed is placed in the chamber.

Step S202: supplying silane gas to the chamber, while opening a predetermined plasma power so as to provide plasma into the chamber, and then forming the inorganic barrier layer on the surface of the first flexible material layer.

Exemplarily, when the inorganic barrier layer 402 (for example, a silicon oxide material layer) is farmed, a chemical vapor deposition (CVD) process may be used to form the inorganic barrier layer 402 on the surface of the first flexible material layer 401 (for example, the first PI material layer). Specifically, in the deposition process, plasma may be provided by a plasma power, and environmental conditions such as silane gas (SiH₄) may be also provided. For example, 50 sccm of SiH₄ may be introduced, and the deposition may be performed under a circumstance of 350° C./1800 mTorr for 870 seconds so as to form an inorganic barrier layer.

In step S103, after forming the inorganic barrier layer, performing a plasma bombardment treatment on the surface of the inorganic barrier layer so that hydroxyl groups are present thereon, thereby improving the wettability of the surface of the inorganic barrier layer.

In an embodiment of the present disclosure, after forming the inorganic barrier layer 402 (for example, silicon oxide or silicon nitride), a plasma treatment is directly performed on the surface of the inorganic barrier layer 402 to modify the surface thereof so that hydroxyl groups are present thereon, as a result, the surface wettability of the silicon oxide material layer is improved to ensure that the second flexible material layer 403 (for example, the second PI film layer) can be well attached to the inorganic barrier layer 402.

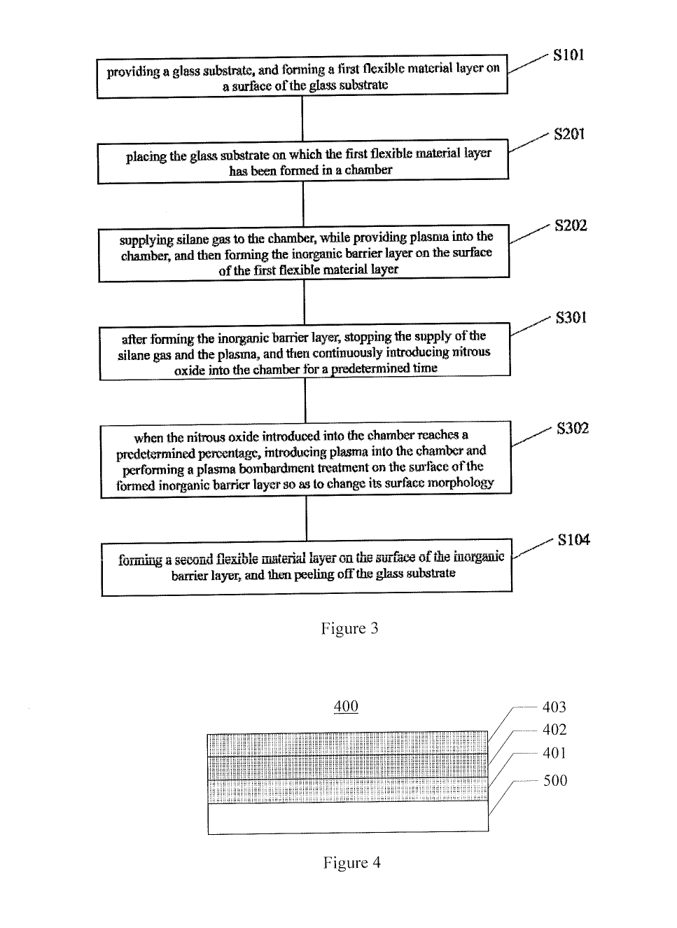

Specifically, as shown in FIG. 3, in an exemplary embodiment of the present disclosure, Step S103, i.e., after forming the inorganic barrier layer 402, performing a plasma bombardment treatment on the surface of the inorganic barrier layer 402, may include the following steps:

Step S301: after forming the inorganic barrier layer, stopping the supply of the silane gas, turning off the predetermined plasma powder, and then continuously introducing nitrous oxide into the chamber for a predetermined time.

Exemplarily, after forming the inorganic barrier layer 402, the plasma power is turned off, the supply of the plasma and the silane gas for the preparation process of the inorganic barrier layer 402 are stopped, and the environment in the chamber is changed to facilitate the performing of the subsequent plasma bombardment treatment. In this embodiment, dinitrogen monoxide (N₂O) is continuously supplied into the chamber for a predetermined time. The predetermined time may be 20 to 300 seconds, and may specifically be 30 seconds, 50 seconds, 70 seconds, 90 seconds, 110 seconds, 130 seconds, or 150 seconds, and the like. The predetermined time is not particularly limited as long as the amount of nitrous oxide introduced into the chamber is sufficient within this time range.

Step S302: when the nitrous oxide introduced into the chamber reaches a predetermined percentage, introducing plasma into the chamber and performing a plasma bombardment treatment on the surface of the formed inorganic barrier layer so as to change its surface morphology.

Exemplarily, the predetermined percentage is more than 95%, that is, when the amount of nitrous oxide introduced into the chamber reaches the overwhelming majority, the environment in the chamber has been changed to the condition where it is suitable for a plasma bombardment treatment at this time. Then, the plasma power may be turned on to generate plasma so that the plasma is bombarded to the surface of the formed inorganic barrier layer 402 (for example, silicon oxide material layer) to change its surface morphology. In some embodiments, the time for plasma bombardment treatment on the surface of the inorganic barrier layer 402 is 1 to 10 seconds, preferably, for example, 4 to 6 seconds, more preferably, 5 seconds, and the like. The power of the plasma bombardment treatment may be 1 to 5 kW, and may be, far example, 3 to 5 kW, more preferably 5 kW, or the like.

In the present embodiment, when the surface of the formed inorganic barrier layer 402 is treated by plasma bombardment to change its surface morphology, no specific parameters (for example, device model, energy parameter) limitations are demanded for the plasma power source and the emitted plasma therefrom, as long as the plasma bombardment treatment may be performed under the conditions set forth above. After the plasma bombardment treatment, the plasma power is turned off again, so that the inorganic barrier layer 402 (for example, a silicon oxide material layer) is finally completed, and the surface modification treatment has been also completed at the same time. The inventors have experimentally discovered that, when the plasma bombardment treatment is performed on the surface of the inorganic barrier layer 402 (for example, a silicon oxide material layer), hydroxyl groups are present on the surface, and the morphology of the surface is changed to improve wettability thereof so as to finally ensure that the second flexible material layer 403 (for example, the second PI film layer) can be well attached to the inorganic barrier layer 402. In Step S104, a second flexible material layer is formed on the surface of the inorganic barrier layer, and the substrate is peeled off.

Exemplarily, the second flexible material layer 403 may also be a polyimide material layer, and after the inorganic barrier layer 402 is prepared and subjected to a plasma bombardment treatment, the second polyimide material layer (i.e., the second flexible material layer 403) is formed on the surface of the inorganic barrier layer 402, and then the substrate 500 is peeled off to complete the fabrication of a PI flexible substrate. When the plasma bombardment treatment is performed on the surface of the inorganic barrier layer 402 (for example, a silicon oxide material layer), hydroxyl groups are present on the surface, and the morphology of the surface is changed to improve wettability thereof so as to finally ensure that the second flexible material layer 403 (for example, the second PI film layer) can be well attached to the inorganic barrier layer 402.

It should be noted that, although each step of the method according to the present disclosure is described in a specific order in the drawings, it does not require or imply that these steps must be performed in this particular order, or all the steps shown here must be performed to achieve the desired result.

Moreover, as shown in FIG.4, there is further provided a flexible substrate 400 in an exemplary embodiment. The flexible substrate 400 may include a first flexible material layer 401, an inorganic barrier layer 402, and a second flexible material layer 403. Wherein, the inorganic barrier layer 402 is deposited on the surface of the first flexible material layer 401, and the second flexible material layer 403 is formed on the surface of the inorganic barrier layer 402.

Specifically, the producing process of the flexible substrate 400 may include: providing a substrate 500, and forming a first flexible material layer 401 on a surface of the substrate 500; forming an inorganic barrier layer 402 on a surface of the first flexible material layer 401, wherein the inorganic barrier layer 402 includes at least one of a silicon oxide material layer and a silicon nitride material layer; after forming the inorganic barrier layer 402, performing a plasma bombardment treatment on the surface of the inorganic barrier layer 402 so that hydroxyl groups are present thereon, thereby improving the wettability of the surface of the inorganic barrier layer 402; forming a second flexible material layer 403 on the surface of the inorganic barrier layer 403, and then peeling off the substrate 500.

In an exemplary embodiment, the step of forming an inorganic barrier layer 402 on a surface of the first flexible material layer 401 may include the following steps: placing the substrate 500 on which the first flexible material layer 401 has been formed in a chamber; supplying silane gas to the chamber, while turning on a predetermined plasma power to supply plasma into the chamber, and then forming the inorganic barrier layer 402 on the surface of the first flexible material layer 401.

Moreover, the step (i.e., after forming the inorganic barrier layer 402, performing a plasma bombardment treatment on the surface of the inorganic barrier layer 402) may include the following steps: after forming the inorganic barrier layer 402, stopping the supply of the silane gas, turning off the plasma powder, and then continuously introducing nitrous oxide into the chamber for a predetermined time; when the nitrous oxide introduced into the chamber reaches a predetermined percentage, turning on the predetermined plasma power to introduce plasma into the chamber, and performing a plasma bombardment treatment on the surface of the formed inorganic barrier layer 402 to change its surface morphology.

In the above exemplary embodiments, the predetermined time may be 20 to 300 seconds. The predetermined percentage is more than 95%. The time for a plasma bombardment treatment on the surface of the inorganic barrier layer 402 may be 1 to 10 seconds, and the power of the plasma bombardment treatment may be 1 to 5 kW. Each of the first flexible material layer 401 and the second flexible material layer 403 may be a polyimide material layer.

In an exemplary embodiment of the present disclosure, the step of forming the inorganic barrier layer 402 on the surface of the first flexible material layer 401 may include the following step: depositing the inorganic barrier layer 402 on the surface of the first flexible material layer 401 by a chemical vapor deposition process. Of course, the embodiments of the present disclosure are not limited to the chemical vapor deposition process.

With respect to the flexible substrate in the above embodiments, each film layer has been described in detail in the embodiment according to the method for producing the flexible substrate described above, and no detailed explanation will be made herein.

In addition, in the present exemplary embodiment, a flexible display panel is also provided. The flexible display panel (not shown) may include the flexible substrate 400 described in the above embodiments. For specific contents, reference may be made to the foregoing embodiments, and details are not described herein again. In addition, the flexible display panel may also include other components such as a light emitting component, a package component, and the like. These parts may refer to the prior art and will not be described in detail.

As for the above method for producing an flexible substrate, the flexible substrate, and the flexible display panel provided in the above embodiment, after forming the inorganic barrier layer 402 (for example, silicon oxide or silicon nitride), a plasma treatment is performed directly on the surface of the inorganic barrier layer 402, and the surface of the inorganic barrier layer 402 is modified so that hydroxyl groups are present thereon; as a result, the wettability of the surface of the inorganic barrier layer 402 is improved to ensure that the second flexible material layer 403 (for example, PI film layer) can be well attached to the inorganic barrier layer 402. On the other hand, compared with the prior art, an additional inorganic interface layer is unnecessarily formed to improve the above-mentioned problems such as poor interface adhesion. Therefore, the present embodiments optimize the producing technology of a multilayer flexible substrate (for example, a PI flexible substrate), which enables the entire flexible substrate processing to be completed simply and smoothly, saving the costs, substantially avoiding the problem of poor stress match and impurities caused by an inorganic interface layer, and increasing product yield and quality.

Those skilled in the art will readily recognize other embodiments of the present disclosure upon consideration of the specification and practice of the invention disclosed herein. This application is intended to cover any variations, uses, or adaptations of the present disclosure which follow the general principles of the present disclosure and include any common knowledge or conventional techniques in this technical field not disclosed by the present disclosure. The description and examples are to be considered exemplary only, with the true scope and spirit of the disclosure being indicated by the appended claims.

1. A method for producing flexible substrate, the method comprising:
providing a substrate, and forming a first flexible material layer on a surface of the substrate;
forming an inorganic barrier layer on a surface of the first flexible material layer, wherein the inorganic barrier layer includes at least one of a silicon oxide material layer and a silicon nitride material layer;
after forming the inorganic barrier layer, performing a plasma bombardment treatment on a surface of the inorganic barrier layer; and
forming a second flexible material layer on the surface of the inorganic barrier layer, and then peeling off the substrate.

2. The method for producing flexible substrate according to claim 1, wherein the step of forming the inorganic barrier layer on the surface of the first flexible material layer includes:
placing the substrate on which the first flexible material layer has been formed in a chamber; and
supplying silane gas to the chamber, while providing plasma into the chamber, and then forming the inorganic barrier layer on the surface of the first flexible material layer.

3. The method for producing flexible substrate according to claim 2, wherein the step of after forming the inorganic barrier layer, performing a plasma bombardment treatment on the surface of the inorganic barrier layer includes:
after forming the inorganic barrier layer, stopping the supply of the silane gas and the plasma, and then continuously introducing nitrous oxide into the chamber for a predetermined time; and
after the nitrous oxide introduced into the chamber reaches a predetermined reaction condition, introducing plasma into the chamber and performing a plasma bombardment treatment on the surface of the formed inorganic barrier layer.

4. The method for producing flexible substrate according to claim 3, wherein the predetermined time is 20 to 300 seconds.

5. The method for producing flexible substrate according to claim 3, wherein the predetermined reaction condition includes that the concentration percentage of the nitrous oxide achieves 95% or more.

6. The method for producing flexible substrate according to claim 3, wherein the plasma bombardment treatment on the surface of the inorganic barrier layer is performed for 1 to 10 seconds, and the power of the plasma bombardment treatment is 1 to 5 kW.

7. The method for producing flexible substrate according to claim 1, wherein the step of forming the inorganic barrier layer on the surface of the first flexible material layer includes:
forming the inorganic barrier layer on the surface of the first flexible material layer by a chemical vapor deposition process.

8. The method for producing flexible substrate according to claim 7, wherein each of the first flexible material layer and the second flexible material layer is a polyimide material layer.

9. A flexible substrate, comprising:
a first flexible material layer;
an inorganic barrier layer located on the first flexible material layer, wherein the inorganic barrier layer includes at least one of a silicon oxide material layer and a silicon nitride material layer, the inorganic barrier layer has a surface on which a plasma bombardment treatment has performed, and hydroxyl groups are present on the surface on which the plasma bombardment treatment has performed; and
a second flexible material layer located on the inorganic barrier layer.

10. A flexible display panel, comprising the flexible substrate according to claim 9.
